(19) United States
(12) Patent Application Publication
(10) Pub. No.: US 2026/0188060 A1
(43) Pub. Date: Jul. 2, 2026

(54) METHOD, CONTROL DEVICE, AND SYSTEM FOR DIAGNOSING ABNORMALITIES OF DRIVING APPARATUS

(71) Applicant: SAMSUNG DISPLAY CO., LTD., YONGIN-SI (KR)

(72) Inventors: YEONG-GEUN PARK, Yongin-si (KR); HOYOUN JANG, Yongin-si (KR); JIE-HUN KANG, Yongin-si (KR)

(21) Appl. No.: 19/387,908

(22) Filed: Nov. 13, 2025

(30) Foreign Application Priority Data
Dec. 31, 2024 (KR) 10-2024-0202073

(51) Int. Cl. G07C 5/02; B60L 15/20

(52) U.S. Cl. CPC G07C 5/02; B60L 15/20; B60L 2240/421; B60L 2240/423

(57) ABSTRACT

A method, control device, and system for diagnosing an abnormality of a driving apparatus include obtaining a first torque value of a first motor of the driving apparatus and a second torque value of a second motor of the driving apparatus, calculating a difference value of a difference between the first torque value and the second torque value, determining a number of deviation occurrence time points when the difference value is greater than or equal to a predetermined threshold, determining an abnormal condition in at least one of a first driving wheel connected to the first motor or a second driving wheel connected to the second motor based on the number of deviation occurrence time points, and updating a parameter of the driving apparatus based on the determination of the abnormal condition.

### CROSS-REFERENCE TO RELATED APPLICATION

This non-provisional patent application claims priority under 35 U.S.C. § 119 to Korean Patent Application No. 10-2024-0202073, filed on Dec. 31, 2024, in the Korean Intellectual Property Office, the disclosure of which is incorporated by reference herein in its entirety.

### TECHNICAL FIELD

Embodiments of the present disclosure relate driving apparatus and, more specifically, to a method, a control device, and a system for diagnosing abnormalities of a driving apparatus.

### DISCUSSION OF THE RELATED ART

Electronic devices with mobility functions are widely used. Recently, computer tablet or personal computers (PCs), in addition to small-sized electronic devices such as mobile phones, have been widely adopted as mobile electronic devices.

Such mobile electronic devices may include display apparatuses to support various functions, for example, to provide a user with visual information, such as images or videos. Recently, as electronic components for driving such display apparatuses have been miniaturized, the proportion occupied by display apparatuses in electronic devices has gradually increased. For example, a structure of the mobile electronic devices may be curved to have an angle from a flat state.

Display apparatuses may display an image by applying voltage to a target molecular arrangement of liquid crystals, transforming the molecular arrangement, and utilizing the emission of light from liquid crystal cells caused by the transformation of the molecular arrangement. As a result, changes in optical properties, such as birefringence, polarization, dichroism, and light scattering characteristics, can be converted into visual changes.

In some cases, equipment is often used to transport electronic devices, such as display apparatuses, to accurately position all or a part of an electronic device in a designated location. For example, when precise positioning is not achieved during the process of transporting electronic devices, assembly quality or operational reliability may deteriorate. Thus, stable and accurate positioning of the electronic devices to the corresponding designated locations may be needed.

Accordingly, real-time and precise monitoring of abnormal conditions, which may occur in equipment that transports electronic devices, is essential to maintain equipment stability and product quality. Therefore, monitoring technologies capable of efficiently detecting minor deviations or abnormal movements during transportation are needed.

### SUMMARY

A method for diagnosing an abnormality of a driving apparatus include obtaining a first torque value of a first motor and a second torque value of a second motor of a driving apparatus, computing a difference value based on the first torque value and the second torque value, determining a number of deviation occurrence time points when the difference value is greater than or equal to a predetermined threshold, determining an abnormal condition in at least one of a first driving wheel connected to the first motor or a second driving wheel connected to the second motor based on the number of deviation occurrence time points, and updating a parameter of the driving apparatus based on the abnormal condition.

The method further include identifying the number of the deviation occurrence time points when the first motor and the second motor rotate at a constant angular velocity.

In one aspect, the number of the deviation occurrence time points is reset at a preset time point.

In one aspect, the first driving wheel and the second driving wheel are connected to a same driving shaft.

The method further include computing a difference between the first torque value and the second torque value at a same time point.

The method further include determining an abnormality occurring in the first driving wheel when the first torque value is greater than the second torque value. The method further include determining an abnormality occurring in the second driving wheel when the second torque value is greater than the first torque value.

The method further include determining the abnormal condition at a time value during which the first motor and the second motor rotate at the constant angular velocity.

The method further include determining the abnormal condition in the at least one of the first driving wheel and the second driving wheel based on the time value during which the first motor and the second motor rotate at the constant angular velocity and the number of the deviation occurrence time points.

In one aspect, the first torque value and the second torque value are obtained at a preset time interval. In one aspect, the preset time interval is greater than or equal to 0.5 seconds.

A control device including at least one memory, and at least one processor. The at least one processor is configured perform operations including obtaining a first torque value of a first motor and a second torque value of a second motor of a driving apparatus, computing a difference value based on the first torque value and the second torque value, determining a number of deviation occurrence time points when the difference value is greater than or equal to a predetermined threshold, determining an abnormal condition in at least one of a first driving wheel connected to the first motor or a second driving wheel connected to the second motor based on the number of deviation occurrence time points, and updating a parameter of the driving apparatus based on the abnormal condition.

The at least one processor is configured to perform operations further including identifying the number of the deviation occurrence time points when the first motor and the second motor rotate at a constant speed.

In one aspect, the first driving wheel and the second driving wheel are connected to a same driving shaft.

The at least one processor is configured to perform operations further including obtaining a time value during which the first motor and the second motor rotate at the constant angular velocity.

The at least one processor is configured to perform operations further including determining the abnormal condition in the at least one of the first driving wheel and the second driving wheel based on the time value during which the first motor and the second motor rotate at the constant angular velocity and the number of the deviation occurrence time points.

A system for diagnosing an abnormality of a transport device including a transport device including a first driving wheel connected to a first motor and a second driving wheel connected to a second motor, and a control device configured to receive a first torque value of the first motor and a second torque value of the second motor, and to diagnose an abnormal condition in at least one of the first driving wheel or the second driving wheel. The control device is configured to obtain the first torque value and the second torque value, to calculate a difference value of a difference between the first torque value and the second torque value, to determine a number of deviation occurrence time points when the difference value is greater than or equal to a predetermined threshold, to determine an abnormal condition in the at least one of the first driving wheel or the second driving wheel based on the number of deviation occurrence time points, and to update a parameter of the driving apparatus based on the determination of the abnormal condition.

The control device is configured to identify the number of the deviation occurrence time points when the transport device travels at a constant angular velocity.

The first driving wheel and the second driving wheel are connected to a same driving shaft.

The control device is configured to determine the abnormal condition at a time value during which the transport device travels at the constant angular velocity.

The control device is configured to determine the abnormal condition in the at least one of the first driving wheel and the second driving wheel based on the time value during which the transport device travels at the constant angular velocity and the number of the deviation occurrence time points.

### BRIEF DESCRIPTION OF THE DRAWINGS

The accompanying drawings attached to the present disclosure illustrate example embodiments of the present disclosure, and are provided to understand the technical idea of the present disclosure, together with the description of the scope of the present disclosure to be provided later, and therefore, it should not necessarily be construed as limited to the matter shown in the drawings in which:

FIG. 1 is a diagram schematically illustrating a system for diagnosing abnormalities of a driving apparatus according to an embodiment of the present disclosure;

FIG. 2 is a diagram schematically illustrating a transport device illustrated in FIG. 1;

FIG. 3 is a block diagram of a control device illustrated in FIG. 1;

FIG. 4 is a flowchart illustrating a method for diagnosing abnormalities of the driving apparatus according to an embodiment of the present disclosure;

FIG. 5 is a graph illustrating data on a first torque value of a first motor and a second torque value of a second motor obtained by the control device;

FIG. 6 is an enlarged view of portion A of FIG. 5;

FIG. 7 is a graph illustrating a difference value between the first torque value of the first motor and the second torque value of the second motor over time;

FIG. 8 is a graph illustrating a cumulative number of deviation occurrence time points over time;

FIG. 9 is a view schematically illustrating a display apparatus that may be transported by the transport device illustrated in FIG. 1; and

FIG. 10 is a cross-sectional view illustrating one sub-pixel of the display apparatus of FIG. 9.

### DETAILED DESCRIPTION

The problem to be solved by the present disclosure is not necessarily limited to the problems mentioned above, and other problems and advantages of the present disclosure, which are not mentioned, may be understood by the following description, and may be more clearly understood by the embodiments of the present disclosure. In addition, it may be appreciated that the problems and advantages to be solved by the present disclosure may be realized by means and combinations thereof indicated in the claims.

While the present disclosure is susceptible to various modifications and alternative forms, example embodiments thereof are shown by way of example in the drawings and are described in detail. Advantages and features of the present disclosure and methods for accomplishing the same may be clearly understood from embodiments described below with reference to the drawings. However, the present disclosure is not necessarily limited to the embodiments disclosed below but may be implemented in various forms.

In the following embodiments, the terms “first,” “second,” and the like have been used to distinguish one component from another, rather than limitative in all aspects. Therefore, in some cases, the first component mentioned below may be the second component within the technical idea of the present invention.

In the following embodiments, singular forms are intended to include plural forms as well, unless the context clearly indicates otherwise. For example, the terms “a”, “an”, “the”, or the like may indicate one or more elements.

In the following embodiments, terms such as “include” and “have” represent that the features or components described in the disclosure are present, and the possibility that one or more other features or components may be added is not excluded in advance.

In the following embodiments, when a unit, area, or component is referred to as being formed on another unit, area, or component, the unit, area, or component can be directly formed on the other unit, area, or component. In some cases, for example, intervening units, areas, or components may be present.

In the following embodiments, terms such as “connecting” or “coupling” two members do not necessarily represent a direct and/or fixed connection or coupling of the two members, unless the context clearly indicates otherwise, and do not preclude another member from being interposed between the two members.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

The same reference numerals may refer to the same components throughout the disclosure and the figures. The shapes, sizes, ratios, angles, numbers, etc. disclosed in the drawings for explaining the embodiments are exemplary, and therefore the present invention is not necessarily limited to the matters illustrated. To the extent that an element is not described in detail with respect to a figure, it may be understood that the element is at least similar to a corresponding element that has been described elsewhere within the present disclosure.

Hereinafter, the example embodiments of the present disclosure are described below in detail with reference to the accompanying drawings, and when the embodiments of the present disclosure are described with reference to the drawings, the same or corresponding components are given the same reference numerals, and repetitive descriptions thereof may be omitted.

Embodiments of the present disclosure provide a method and system for detecting an abnormal condition in a transport device including a first motor and a second motor that drive a first driving wheel and a second driving wheel, respectively. The method includes obtaining torque values from each motor during operation, calculating a difference between the torque values at a predetermined time intervals, and identifying deviation occurrence time points when the difference exceeds a predetermined threshold. The system accumulates a count of such deviation time points under a driving condition (e.g., straight-line travel and constant speed) and resets the count at initialization intervals. Based on the cumulative deviation count and a time value representing the stable operation duration, the system computes a diagnostic coefficient to determine the abnormal condition of the driving wheels.

In some embodiments, the control device determines an abnormal condition has occurred when the diagnostic coefficient exceeds a predetermined reference value, and the control device may then update one or more parameters of the driving apparatus to compensate for the degraded driving wheel. The system may also trigger alarms, adjust driving control profiles, or communicate diagnostic data to external systems. By using the torque value analysis without additional sensors, embodiments of the present disclosure enable cost-efficient, accurate, and real-time diagnosis of transport device abnormalities, which increase operational efficiency and reliability of automated transport systems.

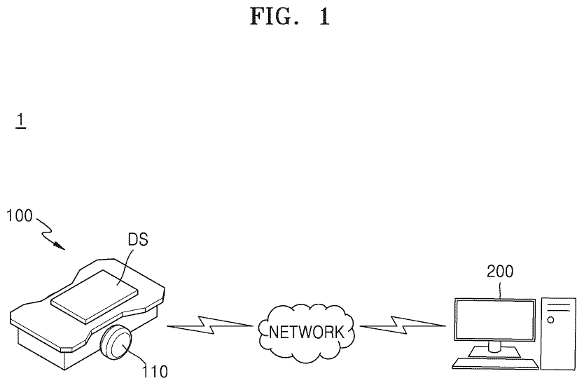

FIG. 1 is a diagram schematically illustrating a system 1 for diagnosing abnormalities of a driving apparatus according to an embodiment of the present disclosure.

Referring to FIG. 1, the system 1 for diagnosing abnormalities of a driving apparatus may include a transport device 100 and a control device 200.

The transport device 100 is a device for transporting and/or returning parts of an electronic device and may transport or return a display apparatus DS or an electronic device equipped with the display apparatus DS during the manufacturing process. n some embodiments, the transport device 100 may also be configured to carry or relocate other types of components, modules, or assemblies, including but not limited to sensors, housings, circuit boards, or packaging materials.

However, the transport device 100 is not necessarily limited thereto, and may include various devices capable of transporting or returning substrates, wafers, or other workpieces handled during manufacturing or inspection processes.

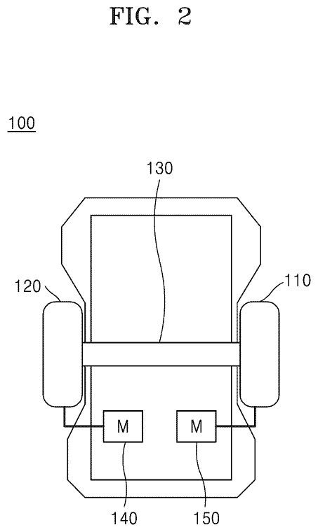

In the present disclosure, the term “driving apparatus” may be referred to as the transport device 100 or as including a first driving wheel 110 and a second driving wheel 120 (shown in FIG. 2) provided in the transport device 100.

The transport device 100 is capable of performing three-axis linear movements or rotational movements by receiving power from an external power source.

In an embodiment, the transport device 100 may include various devices capable of transporting or returning parts of the display apparatus DS or an electronic device equipped with the display apparatus DS. For example, the transport device 100 may be implemented as a cassette stocker, a mask stocker, a tray line balance system, a bridge conveyor, an overhead shuttle, an automated guided vehicle (AGV), a tray overhead shuttle (tray OHS), or other similar transport mechanisms.

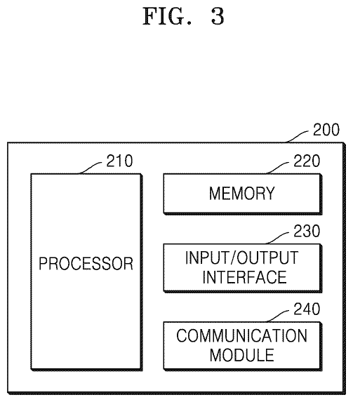

The control device 200 may be implemented as a computer, server, or other processing apparatus capable of executing software for monitoring, analysis, and control functions. The transport device 100 may communicate with the control device 200 via a wired or wireless network, enabling the exchange of operational data, diagnostic results, and control commands. Further details on the control device 200 are described with reference to FIG. 3.

FIG. 2 is a diagram schematically illustrating the transport device 100 illustrated in FIG. 1.

Referring to FIG. 2, the transport device 100 may include the first driving wheel 110, the second driving wheel 120, a driving shaft 130, a first motor 140, and a second motor 150.

The first driving wheel 110 and the second driving wheel 120 may rotate about a preset shaft. For example, the first driving wheel 110 may rotate or be driven by receiving power (e.g., electrical signal or voltage) from the first motor 140, and the second driving wheel 120 may rotate or be driven by receiving power from the second motor 150.

The first driving wheel 110 and the second driving wheel 120 may be connected to the driving shaft 130. For example, when the transport device 100 travels in a straight line, the first driving wheel 110 and the second driving wheel 120 may rotate about the same shaft (e.g., via the driving shaft 130). In some cases, during straight-line travel of the transport device 100, the first driving wheel 110 and the second driving wheel 120 may rotate about the driving shaft 130. In some cases, the first driving wheel 110 and the second driving wheel 120 may rotate at a same rotational speed. In some cases, the rotational speed may be referred to as the angular velocity (e.g., a vector), rounds-per-minute (RPM), speed, or velocity.

The first driving wheel 110 and the second driving wheel 120 may have the same physical characteristics, such as the same shape. For example, the first driving wheel 110 and the second driving wheel 120 may have the same diameter, material, weight, or other design attributes.

The first driving wheel 110 and the second driving wheel 120 may be implemented as various driving apparatuses that rotate by receiving power from the first motor 140 and the second motor 150. For example, the first driving wheel 110 and the second driving wheel 120 may include rotating bodies such as wheels or pulleys.

The first motor 140 and the second motor 150 may take the form of various types of driving apparatuses (e.g., motors) that can apply driving power (or capable of transmitting torque) to the first driving wheel 110 and the second driving wheel 120. For example, the first motor 140 and the second motor 150 may include servo motors, stepper motors, direct current (DC) motors, brushless DC (BLDC) motors, alternating current (AC) motors, geared motors, induction motors, linear motors, piezoelectric motors, torque motors, hybrid motors, or other motor types.

Urethane, rubber, or other elastic material may be attached to an outer circumferential surface of each of the first driving wheel 110 and the second driving wheel 120. For example, there materials may cover the outer circumferential surfaces of the first driving wheel 110 and the second driving wheel 120.

When an abnormality occurs in either the first driving wheel 110 or the second driving wheel 120, such as deformation or delamination of the elastic material to the outer circumferential surface of the first driving wheel 110 or the second driving wheel 120, a diameter difference between the first driving wheel 110 and the second driving wheel 120 may occur.

When the transport device 100 with a pair of deformed driving wheels (e.g., a diameter difference between the first driving wheel 110 and the second driving wheel 120) travels in a straight line, the first motor 140 and the second motor 150 may operate with different torques to overcome the diameter difference to move the first driving wheel 110 and the second driving wheel 120 at the same linear velocity. For example, when a wheel has a smaller diameter compared to a wheel having a large diameter, the wheel with the smaller diameter may operate at a higher rotational speed (or velocity) to achieve a same linear velocity as the wheel with the large diameter.

For example, when delamination occurs on the surface of the first driving wheel 110, causing the diameter of the first driving wheel 110 to become relatively larger than the diameter of the second driving wheel 120, there may be a point in time when an angular velocity of the second driving wheel 120 needs to be relatively higher than that of the first driving wheel 110 to maintain the same linear velocity. As a result, the torque of the second motor 150 may be measured as relatively greater than the torque of the first motor 140.

The method, control device 200, and system for diagnosing abnormalities of a driving apparatus of the present disclosure may detect an abnormal condition in at least one of the first driving wheel 110 connected to the first motor 140 and the second driving wheel 120 connected to the second motor 150 by comparing magnitudes of torque between the first motor 140 and the second motor 150. Accordingly, in cases where a minor variation in the diameter of one of the first driving wheel 110 or the second driving wheel 120, caused by surface degradation, delamination, or deformation, may result in a compensatory torque imbalance between the first motor 140 and the second motor150 during straight-line travel. By monitoring these torque differences, embodiments of the present disclosure can detect subtle mechanical abnormalities without relying on additional mechanical sensors, thereby enabling an efficient solution to compact transport systems.

FIG. 3 is a block diagram of the control device 200 illustrated in FIG. 1.

Referring to FIGS. 1 and 3, the control device 200 may receive a first torque value of the first motor 140 and a second torque value of the second motor 150 from the transport device 100, and diagnose an abnormal condition in at least one of the first driving wheel 110 connected to the first motor 140 and the second driving wheel 120 connected to the second motor 150. The control device 200 may include a processor 210, a memory 220, an input/output interface 230, and a communication module 240.

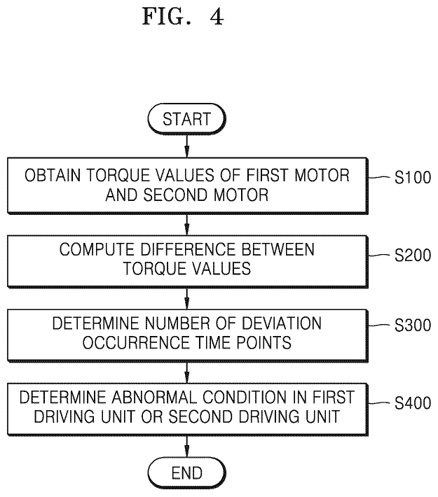

At least one control device 200 and at least one processor 210 of the control device 200 may perform the method for diagnosing abnormalities of the first driving wheel 110 and/or the second driving wheel 120. Further description of the method for diagnosing abnormalities of the first driving wheel 110 and/or the second driving wheel 120 performed by the control device 200 and the processor 210 of the control device 200 may be provided in FIG. 4.

The control device 200 includes the processor 210, the memory 220, the input/output interface 230, and the communication module 240. However, embodiments of the present disclosure are not necessarily limited thereto. For example, control device 200 may include other components such as application program, sensors, or other electronic components. In some cases, other general-purpose components may be further included in the control device 200.

In addition, the processor 210, the memory 220, the input/output interface 230, and the communication module 240 illustrated in FIG. 3 may be implemented as independent devices. In some cases, these components may be implemented as integrated circuits.

The processor 210 may execute instructions of a computer program by performing an arithmetic operation, a logic operation, and/or an input/output operation. For example, the instructions may be provided from the memory 220 or an external device. In addition, the processor 210 may control overall operations of the other components included in the control device 200.

For example, the processor 210 may match at least one source data to each of one or more requests that may occur in a specific domain.

In addition, the processor 210 may retrieve correct context included in the source data for each request based on the result of the matching.

In addition, the processor 210 may generate a database for domain adaptation based on the correct context for each request.

In addition, the processor 210 may generate a response to a user's request using the database.

The processor 210 may be implemented as an array of a plurality of logic gates, or as a combination of a general-purpose microprocessor and a memory in which a program executable by the microprocessor is stored.

For example, the processor 210 may include a general-purpose processor, a central processing unit (CPU), a microprocessor, a digital signal processor (DSP), a controller, a microcontroller, a state machine, or other machines.

In some environments, the processor 210 may include an application-specific semiconductor (ASIC), a programmable logic device (PLD), a field programmable gate array (FPGA), or other logic hardware.

For example, the processor 210 may refer to a combination of processing devices such as a combination of a DSP and a microprocessor, a combination of a plurality of microprocessors, a combination of one or more microprocessors in conjunction with a DSP core, or a combination of any other such configuration.

The memory 220 may include any non-transitory computer-readable medium.

In an embodiment, the memory 220 may include a permanent mass storage device such as a random access memory (RAM), a read-only memory (ROM), a disk drive, a solid-state drive (SSD), a flash memory, or other forms of volatile or non-volatile storage devices.

In an example, the permanent mass storage device such as a ROM, SSD, a flash memory, a disk drive, or a separate permanent storage device which is distinguishable from the memory 220. In addition, the memory 220 may store an operating system (OS) and at least one program code.

These software components may be loaded from a computer-readable recording medium separate from the memory 220. Such a separate computer-readable recording medium may be a recording medium that may be directly connected to the control device 200.

For example, the computer-readable recording medium may include computer-readable recording media in input/output computers, such as a floppy drive, disk, tape, DVD/CD-ROM drive, or a memory card.

The software components may be loaded into the memory 220 through the communication module 240 instead of the computer-readable recording medium. For example, at least one program may be loaded into the memory 220 based on computer programs installed by files provided through the communication module 240 by developers or a file distribution system that distributes installation files for applications.

The input/output interface 230 may serve as a member for interfacing with input and/or output devices (e.g., a keyboard, a mouse, or other electronic accessories) that are connected to or included in the control device 200.

In FIG. 2, the input/output interface 230 is illustrated as a component separate from the processor 210, but is not necessarily limited thereto, and may also be implemented in the processor 210.

The communication module 240 may enable the control device 200 to communicate with external devices, such as the transport device 100, through a network. In addition, the communication module 240 may provide a configuration or functionality for the control device 200 to communicate with other external devices.

For example, control signals, commands, data, or data generated under the control of the processor 210 may be transmitted to the external device through the communication module 240 and a network.

In an embodiment, the control device 200 may include a display module. For example, the display module may display responses generated in response to a user request.

Referring to FIG. 1, the control device 200 may communicate with the transport device 100 through a network.

The control device 200 may obtain information on the first torque value of the first motor 140 and the second torque value of the second motor 150 from the transport device 100 through the network, and the control device 200 may use this information to diagnose the abnormal condition of the transport device 100. In some cases, the control device 200 may use the torque information to diagnose whether an abnormal condition exists in the operation of the transport device 100.

The control device 200 may generate an alarm signal based on the diagnosis results of the abnormal condition of the transport device 100.

The transport device 100 and the control device 200 may communicate with each other and/or with other devices through a network. The network is a comprehensive data communication network that enables different entities to communicate smoothly with each other and may include wired Internet, wireless Internet, and mobile wireless communication networks. In some cases, the network may include a variety of data communication infrastructures.

For example, the network may include a Local Area Network (LAN), a Wide Area Network (WAN), a Value Added Network (VAN), a mobile radio communication network, a satellite communication network, or a combination thereof.

In addition, wireless communication may include, for example, wireless LAN (Wi-Fi), Bluetooth, Bluetooth Low Energy, ZigBee, Wi-Fi Direct (WFD), ultrawideband (UWB), infrared communication (IrDA, Infrared Data Association), Near Field Communication (NFC), and other wireless protocols.

FIG. 4 is a flowchart illustrating a method for diagnosing abnormalities of the driving apparatus according to an embodiment of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

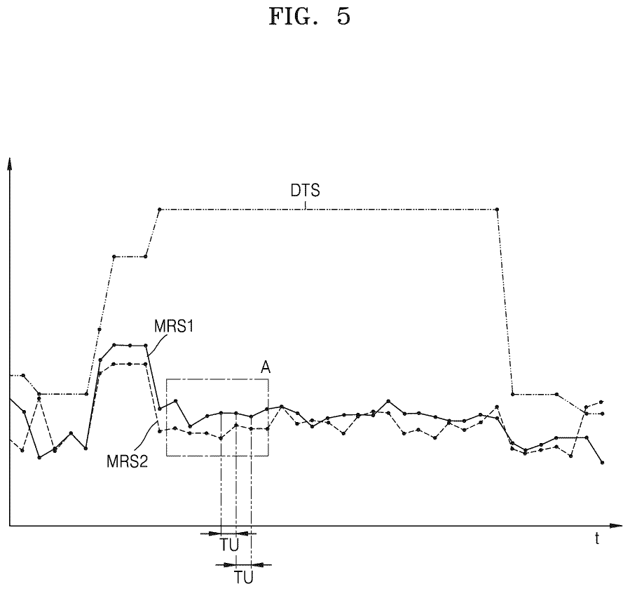

Referring to FIG. 4, the method for diagnosing abnormalities of the driving apparatus may include, at step S100, obtaining a torque value of the first motor 140 and a torque value of the second motor 150 (S100). At step S200, the method includes computing a difference value DV between the torque value of the first motor 140 and the torque value of the second motor 150 (S200). At step S300, the method includes determining a number of deviation occurrence time points DOT when the difference value DV is greater than or equal to a preset value (S300). At step S400, the method includes diagnosing an abnormal condition in at least one of the first driving wheel 110 and the second driving wheel 120 based on the number of deviation occurrence time points DOT (S400). Further detail on each of these operations is described with reference to FIGS. 5-8.

FIG. 5 is a graph illustrating data on the first torque value of the first motor 140 and the second torque value of the second motor 150 obtained by the control device 200.

Referring to FIGS. 4 and 5, at step S100, the control device 200 may obtain the first torque value of the first motor 140 (hereinafter referred to as “first torque value MRS1”) and the second torque value of the second motor 150 (hereinafter referred to as “second torque value MRS2”) based on measurement data received from the transport device 100.

For example, the control device 200 may obtain the first torque value MRS1 and the second torque value MRS2 directly from the first motor 140 and the second motor 150, respectively, or the control device 200 may obtain the first torque value MRS1 and the second torque value MRS2 from a torque measuring device provided in the transport device 100.

In the present disclosure, the “first torque value MRS1” and the “second torque value MRS2” may refer to a magnitude of torque (N·m) applied by the first motor 140 and a magnitude of torque of the second motor 150, respectively.

In an optional embodiment, the “first torque value MRS1” and the “second torque value MRS2” may refer to at least one of angular velocities (RPM), angular accelerations, magnitudes of current and/or voltage applied, power consumptions, power loads applied, or temperatures of the first motor 140 and the second motor 150.

Referring to FIG. 5, the control device 200 may obtain the first torque value MRS1 and the second torque value MRS2 at a predetermined time interval (hereinafter referred to as “set time interval TU”). In some cases, the predetermined time interval may be determined during a sampling period.

For example, the control device 200 may obtain the first torque value MRS1 and the second torque value MRS2 at each set time interval TU, and the set time interval TU for obtaining the first torque value MRS1 may be the same as the set time interval TU for obtaining the second torque value MRS2. In some cases, the same set time interval TU may be applied to the first torque value MRS1 and the second torque value MRS2.

The control device 200 may obtain the first torque value MRS1 and the second torque value MRS2 at the same time point. For example, the control device 200 may obtain the first torque value MRS1 and the second torque value MRS2 measured at the same time point. In some cases, control device 200 may obtain the first torque value MRS1 and the second torque value MRS2 simultaneously at each sampling point.

In an embodiment, the set time interval TU may be greater than or equal to 0.5 seconds, or greater than or equal to 1 second. For example, the set time interval TU may be greater than or equal to 1 second and less than or equal to 3 seconds. In some cases, the set time interval TU may be at least 0.5 seconds or at least 1 second. In some cases, the set time interval TU may range between 1 and 3 seconds.

By obtaining the first torque value MRS1 and the second torque value MRS2 at synchronized time intervals, the control device 200 can compute a difference value representing the absolute difference between the two torque values at each sampling point. When the difference value DV exceeds a predetermined threshold value, the time point may be counted as a deviation occurrence time point, indicating that an abnormal condition is present in the driving behavior of the transport device 100.

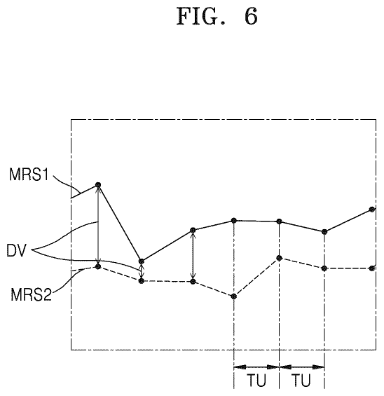

FIG. 6 is an enlarged view of portion A of FIG. 5.

Referring to FIG. 6, the control device 200 may compute a difference between the first torque value MRS1 and the second torque value MRS2.

At step S200, the control device 200 may compute the difference value DV between the first torque value MRS1 and the second torque value MRS2 at the same time point. For example, the control device 200 may perform the calculation for each set time interval TU, using torque values sampled at the same time point.

The difference value DV between the first torque value MRS1 and the second torque value MRS2 may represent a magnitude of the difference between the first torque value MRS1 and the second torque value MRS2 and, for example, may be computed as an absolute value of the difference between the first torque value MRS1 and the second torque value MRS2.

The control device 200 may compute the difference value DV between the first torque value MRS1 and the second torque value MRS2 at each set time interval TU.

For example, the control device 200 may compute the difference value DV between the measured and/or obtained first torque value MRS1 and second torque value MRS2 at each set time interval TU and may continuously extract the difference value DV between the first torque value MRS1 and the second torque value MRS2 at each set time interval TU. In some cases, the control device 200 may continuously compute the difference value DV at each set time interval TU using the measured first torque value MRS1 and the second torque value MRS2.

By calculating the difference value DV at each set time interval TU, embodiments of the present disclosure enable the control device 200 to detect torque imbalances between the first motor 140 and the second motor 150 in real time. This approach facilitates accurate identification of abnormal conditions in the first driving wheel 110 or the second driving wheel 120, without requiring additional mechanical sensors or complex hardware.

In an embodiment, the control device 200 may compute the difference value DV between the first torque value MRS1 and the second torque value MRS2 as a deviation value of the first torque value MRS1 and the second torque value MRS2 according to Equation 1 below:

$$Difference value DV ( \% ) = ( \vert MRS 1 - MRS 2 \vert / max ( MRS 1 , MRS 2 ) ) \times 100 ( \% ) . \qquad [ Equation 1 ]$$

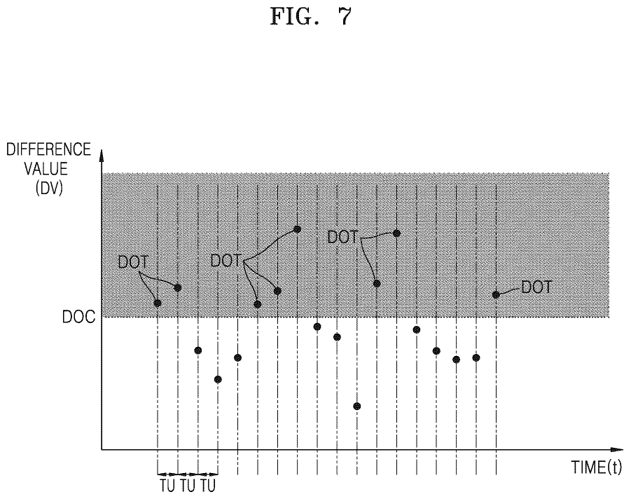

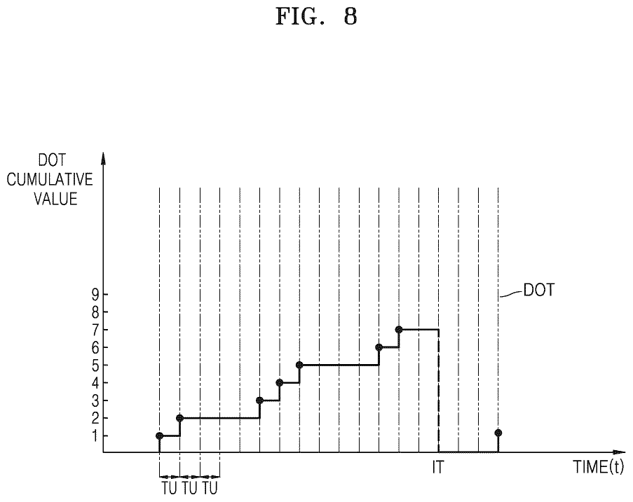

FIG. 7 is a graph illustrating the difference value DV between the first torque value of the first motor 140 and the second torque value of the second motor 150 over time, and FIG. 8 is a graph illustrating a cumulative number of the deviation occurrence time points DOT over time.

Referring to FIGS. 7 and 8, the control device 200 may count the deviation occurrence time points DOT based on the magnitude of the difference value DV between the first torque value MRS1 and the second torque value MRS2.

At step S300, the control device 200 may count a time point at which the difference value DV between the first torque value MRS1 and the second torque value MRS2 is greater than or equal to a preset criterion DOC (hereinafter referred to as “counting criterion”) as the deviation occurrence time point DOT.

For example, when the difference between the first torque value MRS1 and the second torque value MRS2 at a first time point is less than the counting criterion DOC, the control device 200 might not count the first time point as the deviation occurrence time point DOT. However, when the difference between the first torque value MRS1 and the second torque value MRS2 at a second time point is greater than or equal to the counting criterion DOC, the control device 200 may count the second time point as the deviation occurrence time point DOT.

The first time point may be different from the second time point by the set time interval TU. As used herein, a “time point” refers to a discrete moment in time at which the control device 200 obtains the first torque value MRS1 and the second torque value MRS2 based on the set time interval TU. Each time point corresponds to a sampling instance used for diagnostic evaluation. In some cases, a first time point and the second time point may be consecutive or sequentially spaced apart. In some cases, the first time point may precede the second time point.

The control device 200 may distinguish a time point at which the difference value DV between the first torque value MRS1 and the second torque value MRS2 is detected to be greater than the counting criterion DOC as the deviation occurrence time point DOT.

For example, the control device 200 may distinguish a time point at which the difference value DV between the first torque value MRS1 and the second torque value MRS2 is detected to be less than the counting criterion DOC as a non-deviation occurrence time point, and may distinguish a time point at which the difference value DV between the first torque value MRS1 and the second torque value MRS2 is detected to be greater than or equal to the counting criterion DOC as the deviation occurrence time point DOT.

The control device 200 may count the deviation occurrence time point DOT at each set time interval TU.

Referring to FIG. 7, the control device 200 may determine whether the computed difference value DV at each set time interval TU is greater than or equal to the counting criterion DOC, and may count the time point at which the difference value DV is greater than or equal to the counting criterion DOC as the deviation occurrence time point DOT. For example, the control device 200 may determine whether the computed difference value DV at each set time interval TU by registering the corresponding time point that equals or exceeds the counting criterion DOC as a deviation occurrence time point (DOT).

In an embodiment, the counting criterion DOC may be a deviation of 5% or more and 40% or less, 10% or more and 30% or less, or 15% or more and 20% or less. In an embodiment, the counting criterion DOC may correspond to a torque deviation ranging from 5% to 40%, 10% to 30%, or 15% to 20%.

Accordingly, the counting criterion DOC may be set to be approximately 5 to 20% higher than the deviation between the first torque value MRS1 and the second torque value MRS2 during the normal operation of the transport device 100, thereby effectively detecting abnormalities of the transport device 100.

At step S300, the control device 200 may count the deviation occurrence time points DOT when the transport device 100 is traveling in a straight line, and may temporarily suspend the counting of the deviation occurrence time points DOT when the transport device 100 is traveling along a curved path.

The control device 200 may count the deviation occurrence time points DOT when the transport device 100 is traveling at a constant speed (e.g., linear speed), and may temporarily suspend the counting of the deviation occurrence time points DOT when the transport device 100 is traveling at a variable speed.

The control device 200 may count the deviation occurrence time points DOT when the first motor 140 and the second motor 150 are rotating at a constant speed, and may temporarily suspend the counting of the deviation occurrence time points DOT when the first motor 140 and the second motor 150 are rotating at a variable speed.

The control device 200 may count the deviation occurrence time points DOT when the first motor 140 and the second motor 150 are rotating on the same rotational shaft, and may temporarily suspend the counting of the deviation occurrence time points DOT when the first motor 140 and the second motor 150 are rotating on different rotational shafts.

The control device 200 may count the deviation occurrence time points DOT when the first motor 140 and the second motor 150 are rotating with the driving shaft 130 as the rotational shaft, and may temporarily suspend the counting of the deviation occurrence time points DOT when at least one of the first motor 140 and the second motor 150 is rotating around a shaft other than the driving shaft 130.

Referring to FIG. 8, the control device 200 may cumulatively count the number of deviation occurrence time points DOT.

The control device 200 may cumulatively count and update the number of deviation occurrence time points DOT at each set time interval TU. Hereinafter, the cumulative count of the deviation occurrence time points DOT may be referred to as a cumulative value of the deviation occurrence time points DOT.

The control device 200 may update the cumulative value of the deviation occurrence time points DOT at each set time interval TU. For example, when the deviation occurrence time point DOT is detected, the control device 200 may update the cumulative value by adding 1 to an existing cumulative value of the deviation occurrence time points DOT. For example, when a deviation occurrence time point DOT is detected, the control device 200 may increment the cumulative count by 1.

For example, at first to sixth time points, which are temporally spaced apart by the set time interval TU, when the difference value DV between the first torque value MRS1 and the second torque value MRS2 is greater than the counting criterion DOC at the first time point, the second time point, and the sixth time point, the control device 200 may count the first time point, the second time point, and the sixth time point as deviation occurrence time points DOT, and the cumulative number of the deviation occurrence time points DOT up to the sixth time point may be 3. For example, at six consecutive time points spaced by the set time interval TU, if the difference value DV exceeds the counting criterion DOC at the first, second, and sixth time points, the control device 200 may count those as deviation occurrence time points DOT. Thus, the cumulative count of DOTs up to the sixth time point would be 3.

At step S300, the control device 200 may reset the counted number of deviation occurrence time points DOT at a preset time point, which may be referred to as an initialization time point IT.

The control device 200 may reset the cumulative value of the deviation occurrence time points DOT at each initialization time point IT. For example, the control device 200 may reset the cumulative value of the deviation occurrence time points DOT to “0” at each initialization time point IT.

Accordingly, instead of determining an abnormal condition of at least one of the first driving wheel 110 connected to the first motor 140 and the second driving wheel 120 connected to the second motor 150 based on the cumulative value of the deviation occurrence time points DOT, the abnormal condition of the first driving wheel 110 and/or the second driving wheel 120 may be determined by using the cumulative value of the deviation occurrence time points DOT accumulated over a specific time period, thereby taking into account the occurrence frequency of the deviation occurrence time points DOT. Accordingly, the control device 200 may determine an abnormal condition of the first driving wheel 110 and/or the second driving wheel 120 based on the number of deviation occurrence time points DOT detected within a predetermined time period.

In an embodiment, the initialization time point IT may be set to a specific time point during the day. For example, the initialization time point IT may be set to midnight 00:00.

In an embodiment, a time interval between one initialization time point IT and the adjacent initialization time point IT may be n hours. For example, n may be 24. In some cases, n may be an integer greater than 1 and less than 24.

driving wheeldriving wheelAt step S400, the control device 200 may diagnose an abnormal condition in at least one of the first driving wheel 110 and/or the second driving wheel 120 when the cumulative value of the deviation occurrence time points DOT is greater than or equal to a preset value (hereinafter referred to as “diagnostic criterion value”). For example, the control device 200 may diagnose an abnormal condition when the cumulative number of deviation occurrence time points DOT within a time interval IT equals or exceeds a preset threshold value.

The control device 200 may determine whether the cumulative count of the deviation occurrence time points DOT has a value greater than or equal to the diagnostic criterion value. For example, the control device 200 may determine, at each set time interval TU, whether the cumulative count of the deviation occurrence time points DOT has a value greater than or equal to the diagnostic criterion value.

In an embodiment, the diagnostic criterion value may be greater than or equal to 50 and less than or equal to 500, greater than or equal to 100 and less than or equal to 300, or greater than or equal to 150 and less than or equal to 250. For example, the diagnostic criterion value may range from 50 to 500, 100 to 300, or 150 to 250. However, the diagnostic criterion value is not necessarily limited thereto, and may be set differently based on the type of the first driving wheel 110 and/or the second driving wheel 120, the type of the first motor 140 and/or the second motor 150, the type of the transport device 100, and other system characteristics.

As a result, this method reduces an occurrence rate of misdiagnosing an abnormality in the first motor 140 and/or the second motor 150 due to data at an initial driving time point (e.g., the initial startup phase) of motors, in which deviations are more likely to occur.

In the diagnosing of the abnormal condition in at least one of the first driving wheel 110 and the second driving wheel 120, the control device 200 may obtain a time value DTS during which the transport device 100 travels at a constant speed.

In the present disclosure, the “time value DTS during which the transport device 100 travels at a constant speed” may be represent a value obtained by dividing a time during which the transport device 100 travels at a constant speed by the set time interval TU, or as a value obtained by dividing the time during which the transport device 100 travels at a constant speed by the set time interval TU with decimal value optionally discarded.

For example, the “time value DTS during which the transport device 100 travels at a constant speed” may refer to the number of elapsed set time intervals TU during which the transport device 100 travels at a constant speed, or the number of the first torque value MRS1 or the second torque value MRS2 obtained during the transport device 100 travels at a constant speed.

In the diagnosing of the abnormal condition in at least one of the first driving wheel 110 connected to the first motor 140 and the second driving wheel 120 connected to the second motor 150, the control device 200 may obtain the time value DTS during which the first motor 140 and the second motor 150 rotate at a constant speed.

In the present disclosure, the “time value DTS during which the first motor 140 and the second motor 150 rotate at a constant speed” may be a value that is obtained by dividing a time during which the first motor 140 and the second motor 150 rotate at a constant speed by the set time interval TU, or as a value obtained by dividing the time during which the first motor 140 and the second motor 150 rotate at a constant speed by the set time interval TU and discarding the decimal value. Accordingly, the time value DTS for motor rotation may also be expressed as the number of TU intervals in which both motors operate at constant speed, with fractional intervals optionally excluded.

For example, the “time value DTS during which the first motor 140 and the second motor 150 rotate at a constant speed” may refer to the number of elapsed set time intervals TU during which the first motor 140 and the second motor 150 rotate at a constant speed, or the number of the first torque value MRS1 or the second torque value MRS2 obtained during the first motor 140 and the second motor 150 rotate at a constant speed. In some cases, the time value DTS may represent the number of TU intervals during which both the first motor 140 and the second motor 150 operate at constant speed, or the number of torque measurements obtained during the same time.

The control device 200 may reset the time value DTS during which the transport device 100 travels at a constant speed or the time value DTS during which the first motor 140 and the second motor 150 rotate at a constant speed at each initialization time point IT.

Hereinafter, the time value DTS during which the transport device 100 travels at a constant speed may include information that is reset at each initialization time point IT, and the time value DTS during which the first motor 140 and the second motor 150 rotate at a constant speed may include information that is reset at each initialization time point IT. In some cases, the DTS value may be treated as parameters that are reset at each initialization time point IT.

At step S400, the control device 200 may diagnose an abnormal condition in at least one of the first driving wheel 110 and the second driving wheel 120 based on the time value DTS during which the transport device 100 travels at a constant speed and the number of deviation occurrence time points DOT (e.g., a cumulative value of the deviation occurrence time points DOT).

For example, the control device 200 may diagnose the abnormal condition in at least one of the first driving wheel 110 and the second driving wheel 120 by using a ratio of the time value DTS during which the transport device 100 travels at a constant speed to the cumulative value of the deviation occurrence time points DOT. For example, the control device 200 may compute a ratio of the cumulative number of deviation occurrence time points DOT to the time value DTS, and may diagnose an abnormal condition when the ratio exceeds a predetermined threshold.

For example, the control device 200 may compute a diagnostic coefficient for diagnosing an abnormal condition in at least one of the first driving wheel 110 and the second driving wheel 120 by using the ratio of the time value DTS during which the transport device 100 travels at a constant speed to the cumulative value of the deviation occurrence time points DOT.

The control device 200 may compute the diagnostic coefficient using Equation 2 below:

$$Diagnostic coefficient ( \% ) = ( cumulative value of deviation occurrence time points DOT / time value DTS during which transport device 100 travels at constant speed ) \times 100 ( \% ) . \qquad [ Equation 2 ]$$

At step S400, the control device 200 may diagnose an abnormal condition in at least one of the first driving wheel 110 and the second driving wheel 120 based on the time value DTS during which the first motor 140 and the second motor 150 rotate at a constant speed and the number of deviation occurrence time points DOT (the cumulative value of the deviation occurrence time points DOT).

For example, the control device 200 may diagnose the abnormal condition in at least one of the first driving wheel 110 and the second driving wheel 120 by using the ratio of the time value DTS during which the first motor 140 and the second motor 150 rotate at a constant speed to the cumulative value of the deviation occurrence time points DOT.

For example, the control device 200 may compute the diagnostic coefficient for diagnosing an abnormal condition in at least one of the first driving wheel 110 and the second driving wheel 120 by using the ratio of the time value DTS during which the first motor 140 and the second motor 150 rotate at a constant speed to the cumulative value of the deviation occurrence time points DOT. The diagnostic ratio may be used to derive a diagnostic coefficient, where the diagnostic coefficient is compared to a predetermined threshold to determine whether an abnormal condition has occurred in the first driving wheel 110 and/or the second driving wheel 120.

The control device 200 may compute the diagnostic coefficient using Equation 3 below:

$$Diagnostic coefficient ( \% ) = ( cumulative Value of deviation occurrence time points DOT / time value DTS during which first motor 140 and second motor 150 rotate at constant speed ) \times 100 ( \% ) . \qquad [ Equation 3 ]$$

At step S400, the control device 200 may diagnose that an abnormal condition has occurred in at least one of the first driving wheel 110 and/or the second driving wheel 120 when the computed diagnostic coefficient exceeds a preset reference value.

In an embodiment, the preset reference value may be greater than or equal to 2% and less than or equal to 5%. However, the preset value is not necessarily limited thereto, and may be set differently based on the type of the first motor 140 and/or the second motor 150, the type of the transport device 100, or other system configuration parameters.

When the computed diagnostic coefficient exceeds the preset reference value, the control device 200 may determine that an abnormal condition has occurred in the driving wheel connected to the motor whose average torque value is measured to be higher between the first motor 140 and the second motor 150.

For example, the control device 200 may determine that an abnormality has occurred in the first driving wheel 110 when the torque value of the first motor 140 is greater than the torque value of the second motor 150, and the control device 200 may determine that an abnormality has occurred in the second driving wheel 120 when the torque value of the second motor 150 is greater than the torque value of the first motor 140.

When the system determines that at least one abnormal condition has occurred in at least one of the first driving wheel 110 and/or the second driving wheel 120, the control device 200 may control the operation of an alarm device to generate an alarm.

The method, the control device 200, and the system 1 for diagnosing abnormalities of a driving apparatus can effectively diagnose an abnormal condition of the transport device 100 by comparing torque values of the first motor 140 and the second motor 150 provided in the transport device 100. In some cases, by monitoring torque discrepancies between the first motor 140 and the second motor 150 during constant-speed straight line travel and applying predetermined thresholds, the system can detect wheel-based asymmetries such as delamination or deformation, without the need for additional physical sensors.

According to some embodiment, the control device 200 may update at least one operational parameter of the driving apparatus based on the diagnosed abnormal condition. For example, the control device 200 may adjust a torque limit, reduce a driving speed, switch to a backup control profile, or modify a motor control signal to prevent further degradation or to enable a safe operational mode. The parameter update may occur automatically, without user intervention, and may be stored or logged for future use in adaptive diagnostics or maintenance planning.

In some embodiments, the updated parameter may enable the transport device 100 to continue operating with increased stability or performance, even when one of the driving wheels is degraded. For example, when the first driving wheel 110 exhibits abnormal behavior due to deformation or delamination, the control device 200 may update motor control parameters such that the torque output or rotational speed of the second motor 150 is adjusted to compensate for the discrepancy. Accordingly, the transport device 100 may maintain a straight-line trajectory or operational accuracy despite the degraded state of one of the driving wheels.

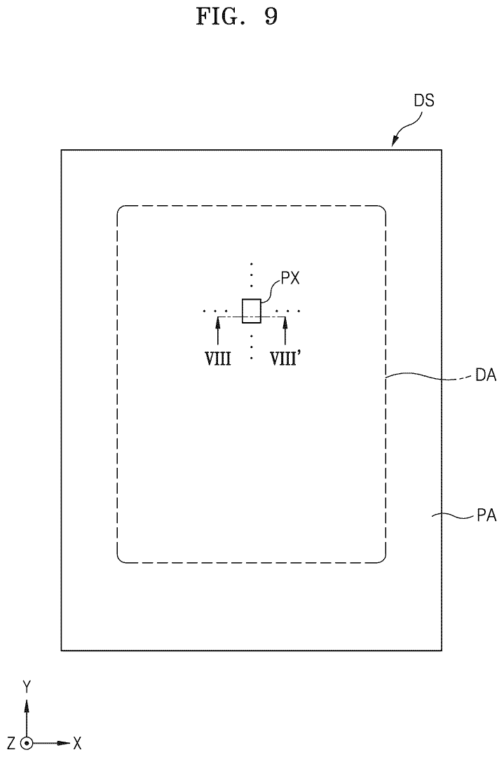

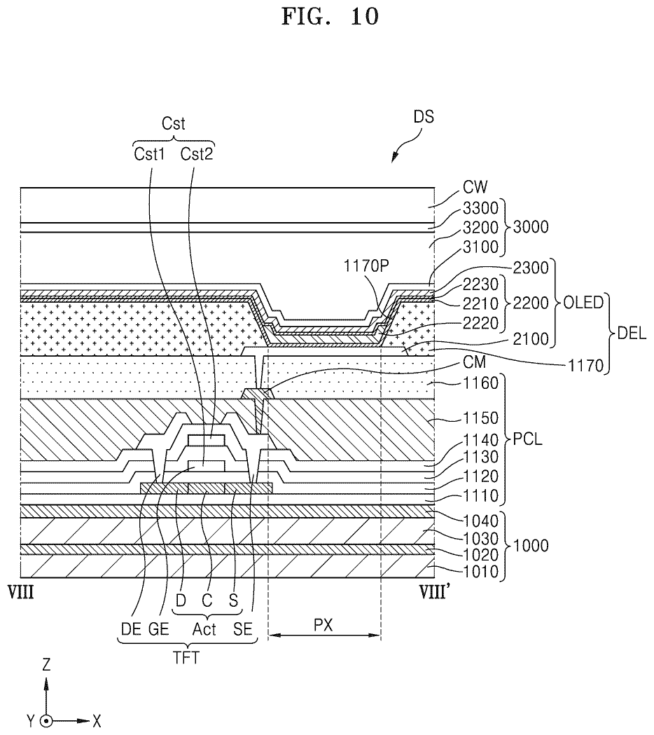

FIG. 9 is a view schematically illustrating the display apparatus DS that may be transported by the transport device 100 illustrated in FIG. 1, and FIG. 10 is a cross-sectional view illustrating one sub-pixel of the display apparatus DS of FIG. 9.

Referring to FIG. 9, the display apparatus DS manufactured according to an embodiment of the present disclosure may include a display area DA and a peripheral area PA surrounding the display area DA. The display apparatus DS may provide an image through an array of a plurality of pixels PX arranged two-dimensionally in the display area DA.

The peripheral area PA is an area that does not provide an image and may completely or partially surround the display area DA. A driver or other electrical components for providing electrical signals or power to a pixel circuit corresponding to each of the pixels PX may be disposed in the peripheral area PA. Pads, which are areas to which electronic elements or printed circuit boards may be electrically connected, may be disposed in the peripheral area PA.

Hereinafter, the display apparatus DS is described as including an organic light-emitting diode (OLED) as a light-emitting element, but, the display apparatus DS of the present disclosure is not necessarily limited thereto.

In an embodiment, the display apparatus DS may be a light-emitting display including an inorganic light-emitting diode, e.g., an inorganic light-emitting display. The inorganic light-emitting diode may include a PN diode having inorganic semiconductor-based materials.

When a voltage is supplied to a PN junction diode in a forward direction, holes and electrons are injected, and energy generated by recombination of the holes and the electrons is converted into light energy to emit light of a predetermined color. The inorganic light-emitting diode may have a width of a several to several hundreds of micrometers, and in some embodiments, the inorganic light-emitting diode may be referred to as a micro light-emitting diode (micro LED).

In an embodiment, the display apparatus DS may be a quantum dot light-emitting display.

In some cases, the display apparatus DS may be used as display screens of various products such as televisions, laptop computers, computer monitors, computer advertising panels, or Internet of Thing (IOT) devices as well as portable electronic devices. For example, the portable electronic devices may include mobile phones, smart phones, tablet computers, personal computers (tablet PCs), mobile communication terminals, electronic organizers, electronic books, portable multimedia players (PMPs), navigation systems, or ultra-mobile PCs (UMPCs).

In addition, the display apparatus DS may be used in wearable devices such as smart watches, watch phones, glass-type displays, or head mounted displays (HMDs).

In addition, the display apparatus DS may be used as a dash board in a vehicle, a center information display (CID) positioned at a center fascia or dashboard of the vehicle, a room mirror display covering for a side-view mirror of the vehicle, or a display screen, which is positioned at the back of a front seat, as entertainment for a passenger in a back seat of a vehicle.

Referring to FIG. 10, the display apparatus DS may include a stacked structure of a substrate 1000, a pixel circuit layer PCL, a display element layer DEL, and an encapsulation layer 3000.

The substrate 1000 may be a multi-layered structure including a base layer including a polymer resin and an inorganic layer. For example, the substrate 1000 may include a base layer including a polymer resin and a barrier layer of an inorganic insulating layer.

For example, the substrate 1000 may include a first base layer 1010, a first barrier layer 1020, a second base layer 1030, and a second barrier layer 1040 that are sequentially stacked. The first base layer 1010 and the second base layer 1030 may include polyimide (PI), polyethersulfone (PES), polyarylate, polyetherimide (PEI), polyethyelenene napthalate (PEN), polyethyeleneterepthalate (PET), polyphenylene sulfide (PPS), polycarbonate (PC), cellulose triacetate (TAC), or/and cellulose acetate propionate (CAP).

The first barrier layer 1020 and the second barrier layer 1040 may include an inorganic insulation material such as silicon oxide, silicon oxynitride, and/or silicon nitride. The substrate 1000 may have flexible characteristics.

The pixel circuit layer PCL may be disposed on the substrate 1000. FIG. 10 illustrates that the pixel circuit layer PCL includes a thin-film transistor TFT, and a buffer layer 1110, a first gate insulating layer 1120, a second gate insulating layer 1130, an interlayer insulating layer 1140, a first planarization insulating layer 1150, and a second planarization insulating layer 1160, which are disposed under and/or above components of the thin-film transistor TFT.

The buffer layer 1110 may reduce or block foreign substances, moisture, or external air, each penetrating from a lower portion of the substrate 1000, and may provide a flat surface on the substrate 1000.

The buffer layer 1110 may include an inorganic insulation material such as silicon oxide, silicon oxynitride, or silicon nitride, and may have a single-layered structure or a multi-layered structure, each including the above-described material.

The thin-film transistor TFT on the buffer layer 1110 includes a semiconductor layer Act, and the semiconductor layer Act may include polysilicon.

Alternatively, the semiconductor layer Act may include amorphous silicon, an oxide semiconductor, an organic semiconductor, or other semiconducting materials suitable for thin-film applications.

The semiconductor layer Act may include a channel area C, a drain area D, and a source area S respectively positioned at both sides of the channel area C. A gate electrode GE may overlap the channel area C.

The gate electrode GE may include a low-resistance metal material. The gate electrode GE may include a conductive material including molybdenum (Mo), aluminum (Al), copper (Cu), titanium (Ti), or the like, and may be formed of a multilayer or single layer including the material.

The first gate insulating layer 1120 between the semiconductor layer Act and the gate electrode GE may include an inorganic insulation material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may include zinc oxide (ZnO) and/or zinc peroxide (ZnO₂).

The second gate insulating layer 1130 may be provided to cover the gate electrode GE. Similar to the first gate insulating layer 1120, the second gate insulating layer 1130 may include an inorganic insulation material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may include zinc oxide (ZnO) and/or zinc peroxide (ZnO₂).

An upper electrode Cst2 of a storage capacitor Cst may be disposed on the second gate insulating layer 1130. The upper electrode Cst2 may overlap the gate electrode GE disposed beneath the upper electrode Cst2. For example, the gate electrode GE and the upper electrode Cst2, which overlap each other with the second gate insulating layer 1130 therebetween, may form the storage capacitor Cst. That is, the gate electrode GE may function as a lower electrode Cst1 of the storage capacitor Cst.

As such, the storage capacitor Cst and the thin-film transistor TFT may be formed to overlap each other. In some embodiments, the storage capacitor Cst may be formed in a non-overlapping configuration with respect to the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be formed as a single layer or multilayer of the above-described material.

The interlayer insulating layer 1140 may cover the upper electrode Cst2. The interlayer insulating layer 1140 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnOₓ), or the like. The zinc oxide (ZnOₓ) may include zinc oxide (ZnO) and/or zinc peroxide (ZnO₂). The interlayer insulating layer 1140 may be a single layer or multilayer including the above-described inorganic insulation material.

A drain electrode DE and a source electrode SE may each be positioned on the interlayer insulating layer 1140. The drain electrode DE and the source electrode SE may respectively be connected to the drain area D and the source area S through contact holes formed in insulating layers disposed below the respective elements. The drain electrode DE and the source electrode SE may include a material with excellent conductivity. The drain electrode DE and the source electrode SE may include a conductive material including molybdenum (Mo), aluminum (Al), copper (Cu), titanium (Ti), or the like, and may be formed of a multilayer or single layer including the material. In an embodiment, the drain electrode DE and the source electrode SE may have a multi-layered structure of Ti/Al/Ti.

The first planarization insulating layer 1150 may cover the drain electrode DE and the source electrode SE. The first planarization insulating layer 1150 may include an organic insulation material such as a general-purpose polymer such as polymethylmethacrylate (PMMA) or polystyrene (PS), a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, or a combination thereof.

The second planarization insulating layer 1160 may be disposed on the first planarization insulating layer 1150. The second planarization insulating layer 1160 may include the same material as the first planarization insulating layer 1150, and may include an organic insulation material such as a general-purpose polymer such as PMMA or PS, a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, and a blend thereof.

The display element layer DEL may be disposed on the pixel circuit layer PCL having the above-described structure. The display element layer DEL includes an organic light-emitting diode OLED as a display element (that is, a light-emitting element), and the organic light-emitting diode OLED may include a stacked structure of a pixel electrode 2100, an intermediate layer 2200, and a common electrode 2300. The organic light-emitting diode OLED may emit, for example, red, green, or blue light, or may emit red, green, blue, or white light. The organic light-emitting diode OLED may emit light through an emission area, and the emission area may be defined as a pixel PX.

The pixel electrode 2100 of the organic light-emitting diode OLED may be electrically connected to the thin-film transistor TFT through contact holes formed in the second planarization insulating layer 1160 and the first planarization insulating layer 1150 and a contact metal CM disposed on the first planarization insulating layer 1150.

The pixel electrode 2100 may include a conductive oxide material such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 2100 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 2100 may further include a film formed of ITO, IZO, ZnO, or In₂O₃ above and/or below the above-described reflective film.

A pixel-defining film 1170 having an opening 1170P exposing a central portion of the pixel electrode 2100 may be disposed on the pixel electrode 2100. The pixel-defining film 1170 may include an organic insulation material and/or an inorganic insulation material. The opening 1170P may define an emission area of light emitted from the organic light-emitting diode OLED. For example, a size/width of the opening 1170P may correspond to a size/width of the emission area. Thus, a size and/or width of the pixel PX may be based on the size and/or width of the opening 1170P of the pixel-defining film 1170.

The intermediate layer 2200 may include an emission layer 2220 formed to correspond to the pixel electrode 2100. The emission layer 2220 may include a polymer or low molecular weight organic material emitting a predetermined color of light. Alternatively, the emission layer 2220 may include an inorganic light-emitting material or quantum dots.

In an embodiment, the intermediate layer 2200 may include a first functional layer 2210 and a second functional layer 2230 respectively disposed below and on the emission layer 2220. The first functional layer 2210 may include, for example, a hole transport layer (HTL) or may include an HTL and a hole injection layer (HIL). The second functional layer 2230, as a component disposed on the emission layer 2220, may include an electron transport layer (ETL) and/or an electron injection layer (EIL). The first functional layer 2210 and/or the second functional layer 2230 may be a common layer formed to entirely cover the substrate 1000 as with the common electrode 2300 described below.

The common electrode 2300 is disposed above the pixel electrode 2100, and may overlap the pixel electrode 2100. The common electrode 2300 may include a conductive material with a low work function. For example, the common electrode 2300 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the common electrode 2300 may further include a layer including materials such as ITO, IZO, ZnO, or In₂O₃ formed on the (semi) transparent layer including the above-described material. The common electrode 2300 may be integrally formed to entirely cover the substrate 1000.

The encapsulation layer 3000 is disposed on the display element layer DEL, and may cover the display element layer DEL. The encapsulation layer 3000 may include at least one inorganic encapsulation layer and at least one organic encapsulation layer, and in an embodiment, FIG. 10 illustrates that the encapsulation layer 3000 includes a first inorganic encapsulation layer 3100, an organic encapsulation layer 3200, and a second inorganic encapsulation layer 3300 that are sequentially stacked.

The first inorganic encapsulation layer 3100 and the second inorganic encapsulation layer 3300 may include at least one inorganic material such as aluminum oxide, titanium oxide, tantalum oxide, hafnium oxide, zinc oxide, silicon oxide, silicon nitride, and silicon oxynitride. The organic encapsulation layer 3200 may include a polymer-based material. The polymer-based material may include an acrylic resin, an epoxy-based resin, polyimide, polyethylene, and similar material. In an embodiment, the organic encapsulation layer 3200 may include acrylate. The organic encapsulation layer 3200 may be formed by hardening a monomer or applying a polymer. The organic encapsulation layer 3200 may be transparent.

In some cases, a touch sensor layer may be disposed on the encapsulation layer 3000, and an optical functional layer may be disposed on the touch sensor layer. The touch sensor layer may obtain coordinate information in response to an external input, for example, a touch event. The optical functional layer may reduce the reflectance of light (external light) incident on the display apparatus, and/or may improve the color purity of light emitted from the display apparatus. In an embodiment, the optical functional layer may include a retarder and/or a polarizer. The retarder may be a film type or a liquid crystal coating type and may include a λ/2 retarder and/or a λ/4 retarder. The polarizer may also be a film type or a liquid crystal coating type. The film type may include a stretch-type synthetic resin film, and the liquid crystal coating type may include liquid crystals disposed in a predetermined arrangement. The retarder and the polarizer may further include a protective film.

An adhesive member may be disposed between the touch sensor layer and the optical functional layer. The adhesive member may be any adhesive member generally known in the related art. The adhesive member may be a pressure-sensitive adhesive (PSA).

A cover window CW may be disposed on the encapsulation layer 3000, and when the touch sensor layer and/or the optical functional layer are disposed, the cover window CW may be disposed on the touch sensor layer and/or the optical functional layer. The cover window CW may include at least one of glass, sapphire, and plastic. The cover window CW may include, for example, ultra-thin glass or colorless polyimide. In an embodiment, the cover window CW may have a structure in which a flexible polymer layer is disposed on one surface of a glass substrate, or include only a polymer layer.

The cover window CW may be attached by an adhesive member. The adhesive member may be a liquid optically clear resin (OCR), an optically clear adhesive (OCA) film, and/or a pressure-sensitive adhesive (PSA).

While each of the embodiments described above may be implemented independently, the structures of the respective embodiments may also be applied in combination with each other.

As described above, the present disclosure has been described with reference to the embodiment described with reference to the drawings, but it may be understood that this is merely exemplary, and those of ordinary skill in the art may understand that various modifications and other equivalent embodiments are possible therefrom. Accordingly, the true technical protection scope of the present disclosure should be defined by the technical spirit of the appended claims.

The particular implementations shown and described herein are illustrative examples of the embodiments and are not necessarily intended to otherwise limit the scope of the embodiments in any way.

The use of the terms “a” and “an” and “the” and similar referents in the context of describing the present disclosure (especially in the context of the following claims) are to be construed to cover both the singular and the plural.

Further, recitation of ranges of values herein are merely intended to serve as a shorthand method of referring individually to each separate value falling within the range, unless otherwise indicated herein, and each separate value is incorporated into the disclosure as if it were individually recited herein.

Finally, operations of all methods described herein can be performed in any suitable order unless otherwise indicated herein or otherwise clearly contradicted by context. The present disclosure is not necessarily limited to the described order of the operations.

The use of any and all examples, or exemplary terms provided herein, is intended merely to better illuminate the present disclosure and does not pose a limitation on the scope of the present disclosure unless otherwise claimed.

Further, numerous modifications and adaptations may be readily apparent to one of ordinary skill in the art without departing from the spirit and scope of the present disclosure.

A method, a control device, and a system for diagnosing abnormalities of a driving apparatus can effectively diagnose an abnormal condition in a transport device by comparing torque values of a first motor and a second motor provided in the transport device.

However, the effects obtainable through the present disclosure are not necessarily limited to the effects skilled above, and other technical effects not mentioned may be understood apparently by those skilled in the art to which the present disclosure pertains from the description below.

What is claimed is:

1. A method for diagnosing an abnormality of a driving apparatus, comprising:
obtaining a first torque value of a first motor of the driving apparatus and a second torque value of a second motor of the driving apparatus;
calculating a difference value as a difference between the first torque value and the second torque value;
determining a number of deviation occurrence time points when the difference value is greater than or equal to a predetermined threshold;
determining an abnormal condition in at least one of a first driving wheel connected to the first motor or a second driving wheel connected to the second motor based on the number of deviation occurrence time points; and
updating a parameter of the driving apparatus based on the determination of the abnormal condition.

2. The method of claim 1, wherein determining the number of deviation occurrence time points comprises:
identifying the number of deviation occurrence time points when the first motor and the second motor rotate at a constant angular velocity.

3. The method of claim 1, wherein:
the number of deviation occurrence time points is reset at a preset time point.

4. The method of claim 1, wherein:
the first driving wheel and the second driving wheel are connected to a same driving shaft.

5. The method of claim 1, wherein computing the difference value comprises:
computing a difference between the first torque value and the second torque value at a same time point.

6. The method of claim 1, wherein determining the abnormal condition comprises:
determining an abnormality occurring in the first driving wheel when the first torque value is greater than the second torque value, and
determining an abnormality occurring in the second driving wheel when the second torque value is greater than the first torque value.

7. The method of claim 2, wherein determining the abnormal condition comprises:
determining the abnormal condition at a time value during which the first motor and the second motor rotate at the constant angular velocity.

8. The method of claim 7, wherein determining the abnormal condition comprises:
determining the abnormal condition in at least one of the first driving wheel and the second driving wheel based on the time value during which the first motor and the second motor rotate at the constant angular velocity and the number of deviation occurrence time points.

9. The method of claim 1, wherein:
the first torque value and the second torque value are obtained at a preset time interval.

10. The method of claim 9, wherein:
the preset time interval is greater than or equal to 0.5 seconds.

11. A control device, comprising:
at least one memory; and
at least one processor,
wherein the at least one processor is configured to perform operations comprising:
obtaining a first torque value of a first motor of a driving apparatus and a second torque value of a second motor of the driving apparatus;
determining a number of deviation occurrence time points when the difference value is greater than or equal to a predetermined threshold;
determining an abnormal condition in at least one of a first driving wheel connected to the first motor or a second driving wheel connected to the second motor based on the number of deviation occurrence time points; and
updating a parameter of the driving apparatus based on the determination of the abnormal condition.

12. The control device of claim 11, wherein the at least one processor is configured to perform operations further comprising:
identifying the number of deviation occurrence time points when the first motor and the second motor rotate at a constant angular velocity.

13. The control device of claim 11, wherein:
the first driving wheel and the second driving wheel are connected to a same driving shaft.

14. The control device of claim 12, wherein the at least one processor is configured to perform operations further comprising:
obtaining a time value during which the first motor and the second motor rotate at the constant angular velocity.

15. The control device of claim 14, wherein the at least one processor is configured to perform operations further comprising:
determining the abnormal condition in the at least one of the first driving wheel and the second driving wheel based on the time value during which the first motor and the second motor rotate at the constant angular velocity and the number of deviation occurrence time points.

16. A system for diagnosing an abnormality of a transport device, comprising:
a transport device including a first driving wheel connected to a first motor and a second driving wheel connected to a second motor; and
a control device configured to receive a first torque value of the first motor of the transport device and a second torque value of the second motor of the transport device, and to diagnose an abnormal condition in at least one of the first driving wheel or the second driving wheel,
wherein the control device is configured to obtain the first torque value and the second torque value, to calculate a difference value of a difference between the first torque value and the second torque value, to determine a number of deviation occurrence time points when the difference value is greater than or equal to a predetermined threshold, to determine an abnormal condition in the at least one of the first driving wheel or the second driving wheel based on the number of deviation occurrence time points, and to update a parameter of the transport device based on the determination of the abnormal condition.

17. The system of claim 16, wherein:
the control device is configured to identify the number of deviation occurrence time points when the transport device travels at a constant angular velocity.

18. The system of claim 16, wherein:
the first driving wheel and the second driving wheel are connected to a same driving shaft.

19. The system of claim 17, wherein:
the control device is configured to determine the abnormal condition at a time value during which the transport device travels at the constant angular velocity.

20. The system of claim 19, wherein:
the control device is configured to determine the abnormal condition in at least one of the first driving wheel and the second driving wheel based on the time value during which the transport device travels at the constant angular velocity and the number of deviation occurrence time points.
